(19) United States
(12) Patent Application Publication
(10) Pub. No.: US 2002/0179958 A1
(43) Pub. Date: Dec. 5, 2002

(54) SONOS flash cells for embedded memory logic, free of drain turn-on and over-erase

(76) Inventor: Dae Mann Kim, Seoul (KR)

Correspondence Address: ROTHWELL, FIGG, ERNST & MANBECK, P.C., 1425 K STREET, N.W., SUITE 800, WASHINGTON, DC, 20005, US

(21) Appl. No.: 09/955,285

(22) Filed: Sep. 19, 2001

(30) Foreign Application Priority Data
Jun. 2, 2001 (KR) 01-31015

(51) Int. Cl. H01L 29/76

(52) U.S. Cl. 257/314

(57) ABSTRACT

A non-volatile memory apparatus and method of manufacturing the same is disclosed, which uses a silicon-oxide-nitride-oxide-silicon (SONOS) memory cell. The SONOS cell comprises the silicon substrate (S), the dielectric layers of stacked oxide-nitride-oxide (ONO), the gate electrode (S) and the source and drain terminals separated by the gate length. The programming of the cell is done by the injection of channel hot electrons into trap sites in between the oxide and the nitride layer, while erasing is done by discharging those trapped electrons via F-N tunneling. This B/L contacted SONOS cell combines both the inherent advantages of memory operation, free of drain turn-on and over-erase and the ability to harness without modification the existing flash EEPROM technology for mass production. Additionally, this B/L contacted SONOS memory apparatus has practically an identical vertical structure to that of the standard MOSFET, which makes it possible to manufacture high density as well as embedded memory chips with the use of a simpler process.

### BACKGROUND OF THE INVENTION

1. Field of the Invention

The present invention relates to semiconductor devices and fabrication methods, and more particularly, to nonvolatile NOR type SONOS flash EEPROM devices and methods of fabricating nonvolatile semiconductor NOR type SONOS flash EEPROM devices.

2. Description of the Related Art

Semiconductor memory devices for storing data can typically be categorized as either volatile memory devices or nonvolatile memory devices. Volatile memory devices lose their stored data when their power is turned off, while nonvolatile memory devices retain their stored data even when their power supplies are turned off. Nonvolatile memory devices can be classified as MaskROM, EPROM, EEPROM, and Flash EEPROM.

Among the various flash EEPROM cell types, a typical cell structure is a floating gate type flash EEPROM cell, introduced in U.S. Pat. No. 4,203,158 by Froman-Bentchkovsky and U.S. Pat. No. 4,698,787 by Mukherjee.

The operation of a floating gate NOR flash EEPROM device is typically divided into three modes including programming, erasing and reading and equivalent circuit of the floating gate type flash EEPROM is shown in FIG. 1. First, the cell can be programmed using channel hot-electron injection (CHEI) mechanism. In CHEI, the voltages of 10 V and 5 V are applied to the control gate and drain, respectively. Under this bias condition, the current flows in inverted channel and the hot electrons generated near the drain by a drain voltage (VD) can overcome the energy barrier of the silicon oxide, and are injected into the floating gate. In this injection process, the vertical electric field produced by the control gate voltage (VCG) enhances the injection probability and the lateral electric field produced by VD increases the hot carrier generation rate. As the floating gate accumulates the charge, the threshold voltage (VTH) shifts to the positive direction on the VCG axis, ˜7.0 V.

In an erase operation, injected electrons are discharged to the source side or the channel side. For the channel side erase for example, −10 V/6 V are applied to the control gate and substrate, respectively. In this case, the electrons in the floating gate are discharged in the form of F-N tunneling current in the entire channel area of the cell.

The data ‘1(0)’ can be distinguished by the VTH difference between a programmed cell and un-programmed cell as shown in FIG. 2. In a reading operation, 0.8˜1.0 V and 5.0 V are applied to B/L and control gate, respectively. If VTH of the selected cell is lower than 5.0 V, the cell becomes conductive and if higher than 5.0 V, the cell becomes non-conductive, and this difference in conductivity is detected and amplified for digital signal processing.

The major problems of the-above-mentioned floating gate cell are the drain turn-on and over-erase problems. First, the drain turn-on problems are described with reference to FIGS. 1 and 3. When a cell A is selected for programming, a W/L and a B/L are biased at 5 V and 10 V, respectively. The unselected W/L and B/L are grounded and electrically floated, respectively. Under this bias condition, the drain turn-on phenomenon can occur in unselected cells like B. As shown in FIG. 3, although the unselected W/L is grounded, the floating gate is capacitively coupled to VD of 5 V, and the channel of the cell B can therefore be inverted weakly or strongly, depending on erased VTH. If the resulting total leakage current is larger than the driving capability of the charge pumping circuitry for the B/L, the required level of VD of 5V, for programming, cannot be attained at cell A. As a result, the cell A cannot be programmed successfully, and even a snapback induced catastrophic failure in programming can occur, as discussed in IEEE Transactions on Electron Devices, Vol. 46, pp. 2240-2243, 1999. The coupled floating gate voltage V_{FG} is given by

$${V}_{FG} = {α}_{D} {V}_{D} + \frac{{Q}_{FG}}{{C}_{T}} \qquad ( 1 )$$

where the total capacitance at the floating gate consists of the capacitance between the floating gate and the control gate, the drain, the source, and the channel, i.e., C_{T}=C_{I}+C_{D}+C_{S}+C_{B}, Q_{FG} denotes the excess electronic charge at the floating gate and α_{D}=C_{D}/C_{T} is the drain coupling ratio. α_{D} increases as the channel length is decreased, because C_{T} decreases with scaling the channel length down, and C_{D} does not change. If α_{D} increases, V_{FG} also increases as clear from equation (1), and therefore, the drain turn-on problem is obviously a serious bottleneck in scaling down.

Second, during an erase operation, the threshold voltage is typically shifted down to 2.0˜3.0 V from programmed state (VTH>6.0 V). A fraction of erased bits have a threshold voltage below 0 V. These bits are called over-erased bits. The problem arising from these over-erased bits is explained with reference to the equivalent circuit of FIG. 4. When the cell A is read and if the threshold voltage of the cell B is below 0V, the current will flow in the B/L, regardless of whether the cell A is programmed or not. Even if the cell A is properly programmed (VTH>6.0V), the current flows in the B/L through the over-erased cells and the cell A is misread as erased, that is, as a program failure.

As discussed, the drain turn-on and over-erase problems are severe obstacles in floating gate NOR flash memory cells. It is therefore very important either to improve on this problem in the floating gate cell or to devise a new cell, free of such problems. In this invention, the B/L contact type SONOS (Silicon-Oxide-Nitride-Oxide-Semiconductor) flash cell is suggested to completely eliminate these problems encountered in floating gate EEPROM cells. Moreover, the BIL contacted SONOS cell possesses an additional advantage for harnessing without modification the existing floating gate flash technology. The possibility of SONOS cells replacing the conventional floating gate NOR flash cell as a mainstream non-volatile high density and high performance memory cell is assessed, together with the possibility for embedded memory applications.

### SUMMARY OF THE INVENTION

It is therefore an object of the present invention to provide semiconductor memory devices having a small unit cell size and methods of forming the same.

It is another object of the present invention to provide a NOR type flash memory cell, free of the drain turn-on and over-erase problems.

These and other objects, features and advantages of the present invention are provided by semiconductor memory devices which comprise an array of NOR type SONOS flash unit cells. These unit cells contain multi layer gate dielectric, viz. silicon dioxide, silicon nitride and silicon dioxide, and the interface trap sites of silicon dioxide and silicon nitride of this cell are used for charge storage site for memory operation, like the floating gate of conventional floating gate NOR type flash cells. The programming and erasing speeds of the SONOS cell are comparable to those of a floating gate type NOR flash cell and the absence of a floating gate in its structure eliminates the drain turn-on phenomenon and makes it possible to be embedded in a single poly layer CMOS logic process. Also, because of the limited number of dischargeable electrons in the embodiment of this invention, the erased VTH exhibits saturated characteristics which mean that the over-erase phenomenon is also eliminated in the SONOS cell.

### BRIEF DESCRIPTION OF THE DRAWINGS

The above objects and advantages of the present invention will become more apparent by describing in detail preferred embodiments thereof with reference to the attached drawings in which:

FIG. 1 shows a NOR flash cell array equivalent circuit; a cell A is selected for programming, and an unselected cell B is under the B/L disturbance, i.e. the drain turn-on problems;

FIG. 2 shows a VTH window in a floating gate memory cell; when charged with electrons VTH is shifted to a larger value of ˜7 V, while when discharged, to a smaller value of ˜2 V;

FIG. 3 shows an equivalent capacitance circuit of the unselected cell B in which a VFG is capacitively coupled with a VD of 5.0 V;

FIG. 4 shows the leakage current path in an over-erased bit; if cell B's VTH is below 0 V, its cell drain current gives rise to enhanced B/L leakage;

FIG. 5 shows a vertical structure of a SONOS cell;

FIG. 6a shows the programming speed of floating gate and SONOS cells; with marginal increase in VD the speed in SONOS is comparable with that of the floating gate cell, FIG. 6b shows the drain turn-on characteristics of a floating gate and SONOS cells; ID versus VD with gate grounded, and FIG. 6c shows the erase characteristics of the SONOS cell free of over-erase and that of the floating gate cell prone to over-erase;

FIGS. 7 through 14 show a SONOS cell process sequence; and

FIG. 15 shows the cross-sectional view of SONOS (b) and floating gate (a) cells indicating the difference in height between the two.

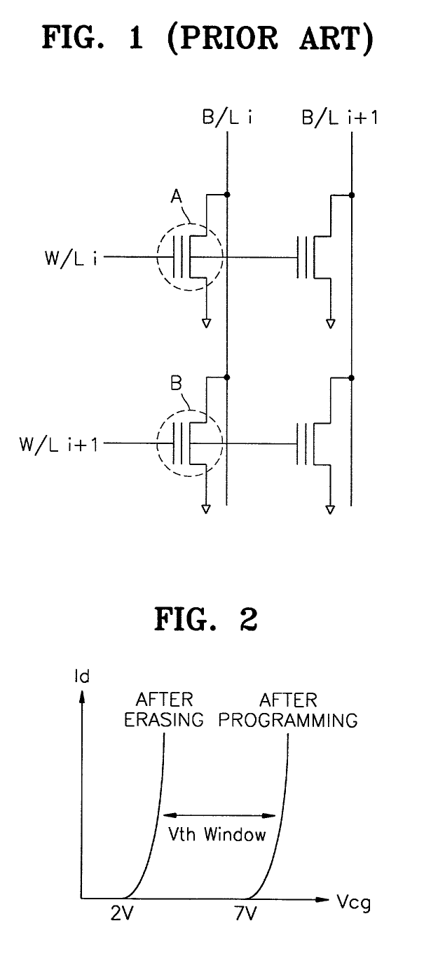

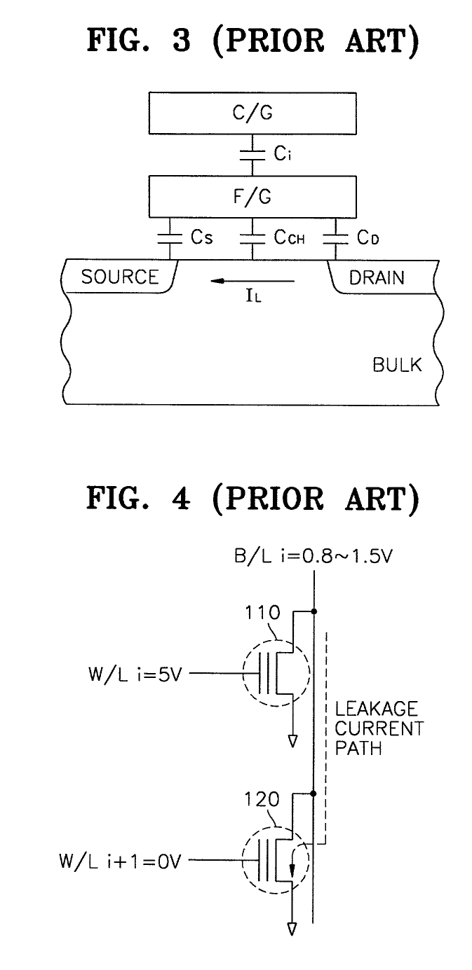

### DETAILED DESCRIPTION OF THE INVENTION

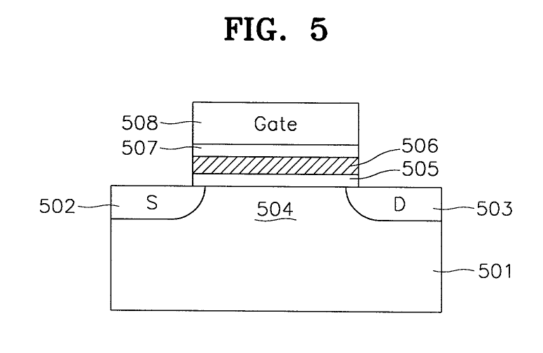

To eliminate the drain turn-on and over-erase problems in the floating gate cell and to realize higher memory density and simpler embedded memory applications using the existing flash EEPROM mass production technology, a SONOS cell is presented in this invention. As shown in FIG. 5, the structure is similar to that of a conventional MOSFET except for the multi-layer dielectric consisting of silicon dioxide/silicon nitride/silicon dioxide. The interface states existing between silicon dioxide and silicon nitride serve as the charge storage sites, eliminating the floating gate in the conventional flash EEPROM cell.

In the following description, the characteristics of SONOS cells, namely the program speed, erase operation and issues relating to drain turn-on and over-erase are presented and discussed.

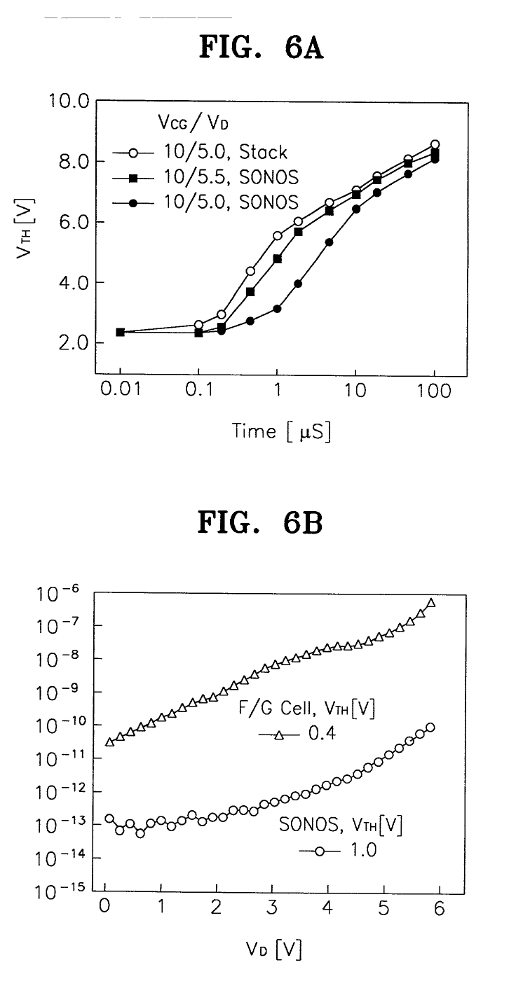

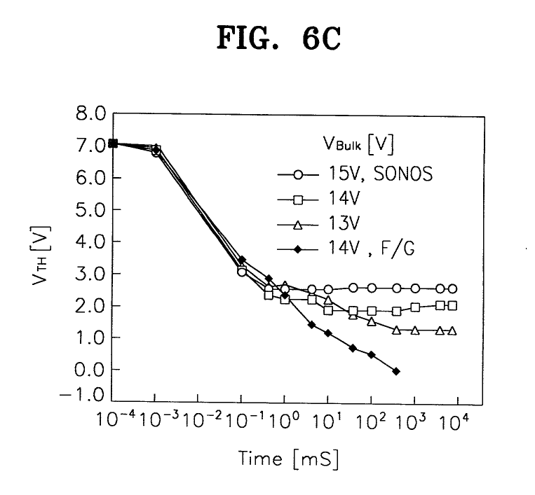

The programming and erasing operation in the fabricated B/L contact type SONOS cell adopts the channel hot electron injection and F-N tunneling processes, respectively. Program speed as monitored via VTH shift as a function of programming time is displayed in FIG. 6a. The SONOS cell has a slower programming speed than a floating gate flash cell at the single cell unit for the same bias conditions. However, with a marginal increase of VD the speed can be made comparable with the floating gate cell. Additionally, the conventional floating gate cell suffers from a drain turn-on problem, and the number of parallel programmable bits is limited to typically 2˜4 bits. In contrast, in a SONOS cell, the drain turn-on effect is completely eliminated so that parallel programmable bits can be increased to about 8˜16 bits. Hence, using the SONOS cell, the program speed at the chip level can be made faster than the case of a conventional floating gate cell.

Drain turn-on characteristics of SONOS and floating gate cells are compared in FIG. 6b, where the drain current is shown versus VD measured with the gate grounded. If the floating gate is removed from the conventional stacked gate flash EEPROM cell as in the SONOS cell, the drain voltage is not capacitively coupled to the floating gate, in which case the drain turn-on phenomenon is eliminated. In the SONOS cell, the leakage current is primarily the junction leakage current of the order of pA˜nA, and is 1000 times lower than that in the floating gate cell. This clearly demonstrates that in the SONOS cell the most serious obstacles in scaling down, namely the drain turn-on problem, are completely eliminated with the removal of the floating gate.

To discharge the locally trapped electrons in the drain side of the cell for an erasing operation, a negative voltage is applied to the gate, with the source/drain electrically floated and the substrate grounded. FIG. 6c shows the VTH shift of the SONOS cell and floating gate cell as a function of erasing time. The erase speeds of SONOS and floating gate cells are about the same.

Note the saturated VTH in the SONOS cell in the limit of long erase time, while in the floating gate cell VTH decreases continuously to reach a level below 0 V exhibiting the over-erase phenomenon. The over-erase free characteristic is an important erase feature of the SONOS cell.

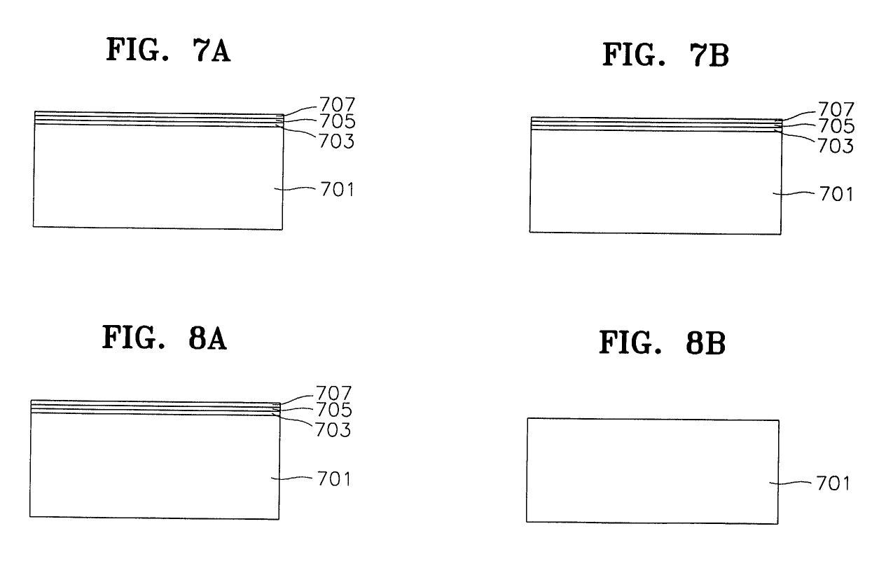

Next, the fabrication sequence for the SONOS cell is described sequentially by using a series of figures from FIG. 7 through FIG. 14. In these figures a and b represent the cell and peripheral area, respectively.

In FIG. 7, thermally grown oxide/LP CVD SiN/CVD oxide was formed on a p-type silicon substrate after an isolation process.

In FIG. 8, to form the gate dielectric of peripheral transistor, an ONO layer in peripheral area is removed through a photo-etch process.

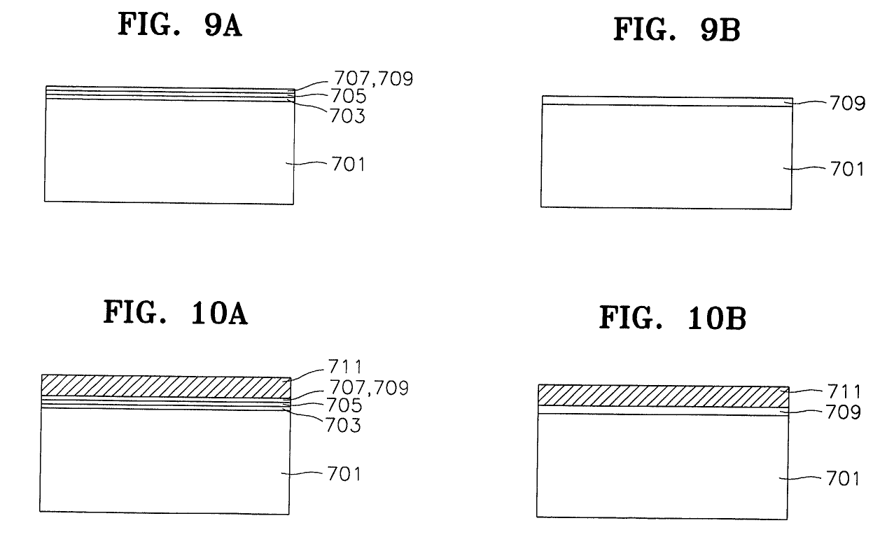

In FIG. 9, the gate dielectric for peripheral transistor is grown thermally on the silicon substrate in the peripheral area. During the growing process, the thickness of the top oxide of ONO in the cell area is increased, however, the increase is negligible because of the nitride layer.

In FIG. 10, the conducting layer for gate electrode, viz. the polycrystalline silicon and tungsten layers are deposited.

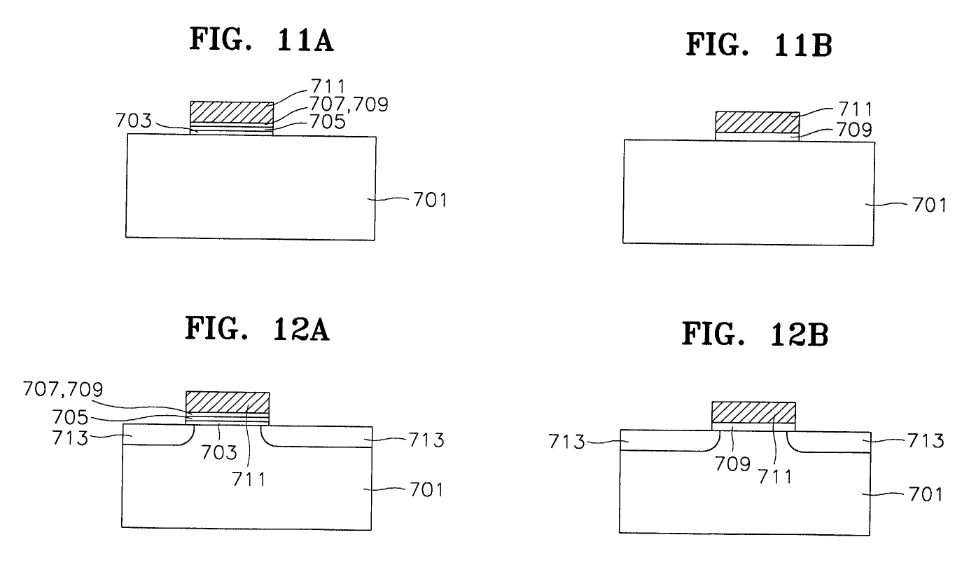

In FIG. 11, the gate electrodes of the cell and the peripheral transistor were patterned with the use of a photolithography process. Since the pattern density and dimensions in the cell area are different from those in the peripheral area, photolithography for each part can be carried out separately.

In FIG. 12, source/drain formation through photo, implantation and diffusion processes is performed repetitively to meet the respective electrical requirements. For example, the drain of the cell has abrupt junction for efficient hot electron generation, while the source of the cell and most of the peripheral junction has a graded junction for reducing hot carrier generation.

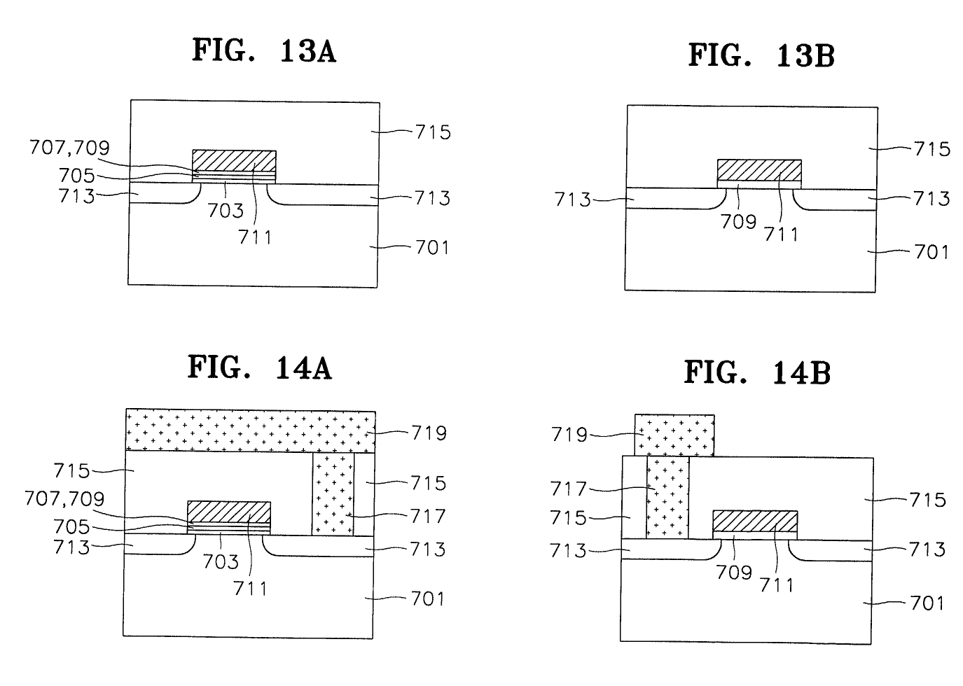

In FIG. 13, the dielectric between gate electrode and metal layer is deposited and planarized. This dielectric formation and planarization process is much simpler than the conventional floating gate process because of the absence of a height difference between the cell and peripheral area.

In FIG. 14, contact hole opening and metalization processes are carried out, which is similar to that of the conventional CMOS process.

After that process, if needed, the conventional processes such as multi-metalization and passivation can be performed.

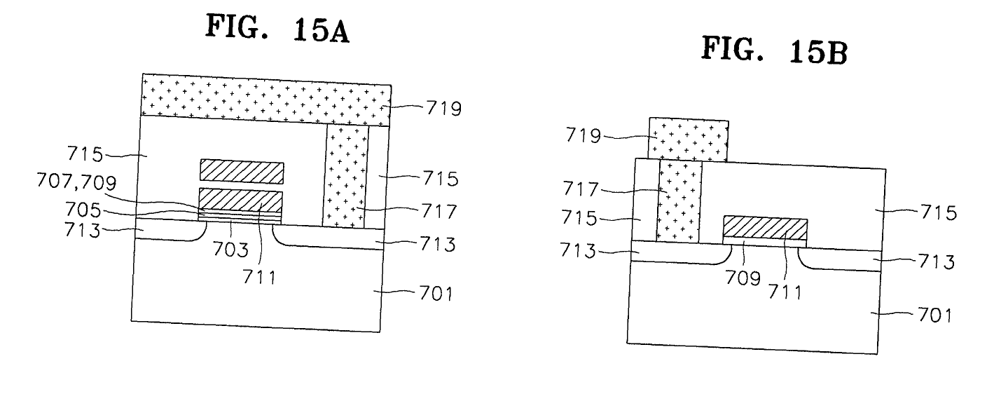

The final structure of the SONOS cell is illustrated in FIG. 15, together with the conventional floating gate cell, for comparison. An important fact to notice is that the structure with the single gate layer in the SONOS cell can make the process condition much simpler. Specifically, because of virtually no height difference between the cell and peripheral areas, the contact hole can be opened simultaneously and easily in both the cell and peripheral areas. The shallow contact hole depth enables the minimum possible space between the cell gate and B/L contact. In summary, the major additional advantage of the B/L contact type-SONOS cell is its process compatibility with the single poly silicon CMOS logic process, which means that the SONOS cell can be readily embedded into logic chips.

What is claimed is:

1. A nonvolatile SONOS NOR flash cell, comprising
a semiconductor substrate of a first conductivity type;
a first silicon dioxide layer formed on the semiconductor substrate;
a silicon nitride layer formed on the first silicon dioxide;
a second silicon dioxide layer formed on the silicon nitride layer;
a gate electrode formed on the second silicon dioxide layer;
source and drain junctions of a second conductivity type displaced by the gate electrode; and
a bit line contact hole formed on the drain junction.

2. The nonvolatile SONOS NOR flash cell of claim 1, wherein programming of the cell is carried out by injecting charge into the trap sites of the interface between silicon dioxide and silicon nitride layers.

3. The SONOS NOR flash cell of claim 1, wherein erasing of the cell is carried out by ejecting charge from the trap sites of the interface between the silicon dioxide and silicon nitride layers.

4. A NOR type nonvolatile semiconductor memory device, wherein a plurality of SONOS cells are arranged in rows and columns, drain junctions of determined SONOS cells share a bit line with each other, and source junctions of the SONOS cells are connected to ground in common, the SONOS cells comprising:
a semiconductor substrate of first conductivity type;
a first silicon dioxide layer formed on the semiconductor substrate;
a silicon nitride layer on the first silicon dioxide layer;
a second silicon dioxide layer formed on the silicon nitride layer;
a gate electrode on the second silicon dioxide layer;
source and drain junctions of a second conductivity type displaced by the gate electrode; and
a bit line contact hole formed on the drain junction.

5. The SONOS NOR flash cell of claim 1, wherein programming of the cell is carried out by injecting charge into the trap site between the silicon dioxide and silicon nitride layers.

6. The SONOS NOR flash cell of claim 1, wherein erasing of the cell is carried out by ejecting charge from the trap site between the silicon dioxide and silicon nitride layer.

7. A method for forming a nonvolatile semiconductor memory device containing SONOS cells, comprising the steps of:
(a) performing a device isolation process on a semiconductor substrate;
(b) forming a first silicon dioxide layer, a silicon nitride layer, and a second silicon dioxide layer on the semiconductor substrate;
(c) covering the first silicon dioxide layer, the silicon nitride layer, the second silicon dioxide layer on a memory cell while removing the first silicon dioxide layer, the silicon nitride and the second silicon dioxide in a peripheral area;
(d) forming a third silicon dioxide layer after step (c);
(e) forming a gate electrode on the third silicon dioxide layer by deposition and patterning of poly-silicon and tungsten silicide;
(f) forming source and drain junctions using the gate electrode as a mask;
(g) forming a bit line contact hole with the use of a photo/etching process after forming an interlayer dielectric layer followed by step (e); and
(h) forming a bit line by patterning the metal after filling the contact hole.

8. The method of claim 7, wherein in step f) the concentration of the junction of the source and drain is adjusted by repetition of a photolithographic process on the source and drain.
